(19) United States
(12) Patent Application Publication
(10) Pub. No.: US 2020/0328138 A1
(43) Pub. Date: Oct. 15, 2020

(54) SEMICONDUCTOR DEVICE, ELECTRONIC DEVICE, ELECTRONIC EQUIPMENT, AND METHOD FOR MANUFACTURING SEMICONDUCTOR DEVICE

(71) Applicant: FUJITSU LIMITED, Kawasaki-shi (JP)

(72) Inventors: Tsuyoshi Yamamoto, Kawasaki (JP); Michimasa AOKI, Kawasaki (JP); Keizou Takemura, Kawasaki (JP)

(73) Assignee: FUJITSU LIMITED, Kawasaki-shi (JP)

(21) Appl. No.: 16/826,925

(22) Filed: Mar. 23, 2020

(30) Foreign Application Priority Data
Apr. 9, 2019 (JP) 2019-074218

(51) Int. Cl. H01L 23/44; H01L 23/373; H01L 23/367

(52) U.S. Cl. CPC H01L 23/44; H01L 23/367; H01L 23/3735

(57) ABSTRACT

A semiconductor device includes a semiconductor chip; a heat transfer plate joined to an upper surface of the semiconductor chip; a first adhesive material provided on an upper surface of the heat transfer plate; a radiator whose lower surface is joined to the upper surface of the heat transfer plate via the first adhesive material; a second adhesive material that is provided on an outer peripheral surface of the heat transfer plate, and joins the upper surface of the semiconductor chip and the lower surface of the radiator; and a groove that is formed on the lower surface of the radiator and extends along the outer peripheral surface of the heat transfer plate.

### CROSS-REFERENCE TO RELATED APPLICATION

This application is based upon and claims the benefit of priority of the prior Japanese Patent Application No. 2019-74218, filed on Apr. 9, 2019, the entire contents of which are incorporated herein by reference.

### FIELD

The technique disclosed in the present application relates to a semiconductor device, an electronic device, electronic equipment, and a method for manufacturing a semiconductor device.

### BACKGROUND

As an electronic device, a device including a board and a semiconductor device mounted to the board is known. Furthermore, in recent years, as a technique for improving a cooling performance of this type of electronic device, a technique has been used in which an electronic device is accommodated in an immersion tank that stores a refrigerant liquid, and cooling is performed by immersing the electronic device in the refrigerant liquid.

Moreover, a semiconductor device having the following structure is known. In other words, for example, a known semiconductor device includes a semiconductor chip, a first adhesive material, a radiator, and a second adhesive material. The semiconductor chip is disposed on the board, and a lower surface of the radiator is joined to an upper surface of the semiconductor chip via the first adhesive material. The lower surface of the radiator is formed with a frame part surrounding the semiconductor chip, and the frame part is joined to the board via the second adhesive material. Between the second adhesive material joining the frame part to the board, and the first adhesive material joining the radiator to the semiconductor chip, a space is provided. For example, Japanese Laid-open Patent Publication No. 2019-016764, Japanese Laid-open Patent Publication No. 06-077361, Japanese Laid-open Patent Publication No. 06-252301, Japanese Laid-open Patent Publication No. 2004-303869, Japanese Laid-open Patent Publication No. 2007-184501, and the like are disclosed as related art.

### SUMMARY

According to an aspect of the embodiments, a semiconductor device includes a semiconductor chip; a heat transfer plate joined to an upper surface of the semiconductor chip; a first adhesive material provided on an upper surface of the heat transfer plate; a radiator whose lower surface is joined to the upper surface of the heat transfer plate via the first adhesive material; a second adhesive material that is provided on an outer peripheral surface of the heat transfer plate, and joins the upper surface of the semiconductor chip and the lower surface of the radiator; and a groove that is formed on the lower surface of the radiator and extends along the outer peripheral surface of the heat transfer plate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view of electronic equipment according to the present embodiment;

FIG. 2 is a cross-sectional view of a semiconductor device of FIG. 1 and a peripheral portion thereof;

FIG. 3 is a plan view of the semiconductor device of FIG. 1 and a peripheral portion thereof;

FIG. 4 is a view illustrating a first process of a method for manufacturing a semiconductor device according to the present embodiment;

FIG. 5 is a view illustrating a second process of the method for manufacturing the semiconductor device according to the present embodiment;

FIG. 6 is a view illustrating a first process in a first modified example of the method for manufacturing the semiconductor device according to the present embodiment;

FIG. 7 is a view illustrating a second process in the first modified example of the method for manufacturing the semiconductor device according to the present embodiment;

FIG. 8 is a view illustrating a second modified example of the method for manufacturing the semiconductor device according to the present embodiment;

FIG. 9 is a view illustrating a third modified example of the method for manufacturing the semiconductor device according to the present embodiment; and

FIG. 10 is a cross-sectional view of a semiconductor device and a peripheral portion thereof according to a comparative example.

### DESCRIPTION OF EMBODIMENTS

In a semiconductor device, when a pressure in a space between a first adhesive material and a second adhesive material increases due to heat generation of a semiconductor chip, pressure may be applied to the second adhesive material, and a sealing property of the second adhesive material may be impaired. Therefore, when the semiconductor device described above is used for an electronic device to be immersed in a refrigerant liquid, it is assumed that the refrigerant liquid passes through the second adhesive material to reach the first adhesive material, and the first adhesive material is exposed to the refrigerant liquid. When the first adhesive material is exposed to the refrigerant liquid in this way, the first adhesive material may be deteriorated, and thermal conductivity of the first adhesive material may be impaired. In view of the above, it is desirable to suppress impairment of the thermal conductivity of the first adhesive material.

First, an overview of a configuration of electronic equipment according to the present embodiment will be described.

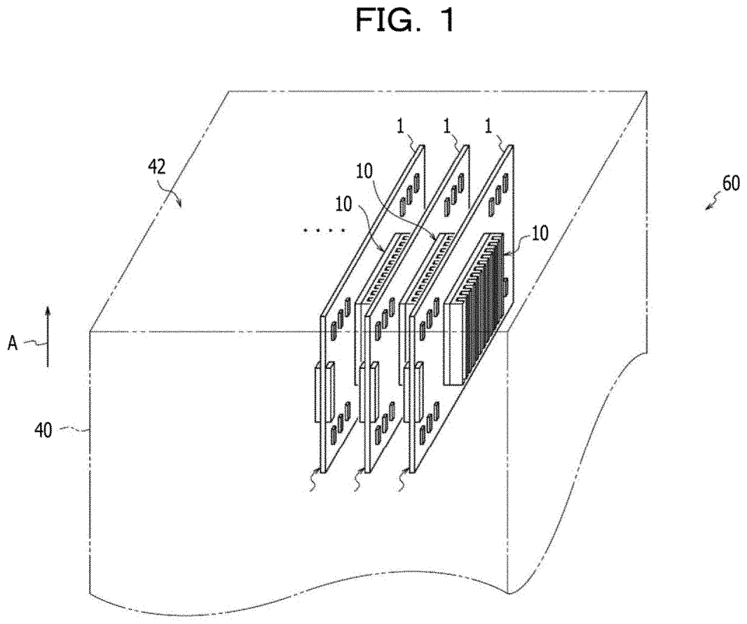

FIG. 1 illustrates electronic equipment 60 according to the present embodiment. As illustrated in FIG. 1, the electronic equipment 60 according to the present embodiment includes an immersion tank 40 and a plurality of electronic devices 50. In FIG. 1, the immersion tank 40 is indicated by an imaginary line (two-dot chain line) to facilitate understanding of arrangement of the plurality of electronic devices 50. The immersion tank 40 stores a refrigerant liquid 42. The refrigerant liquid 42 is, for example, a fluorine-based insulating cooling liquid or mineral oil.

The plurality of electronic devices 50 are accommodated in the immersion tank 40, and are immersed in the refrigerant liquid 42. Each electronic device 50 is cooled by being immersed in the refrigerant liquid 42. The electronic device 50 includes a board 1 and a semiconductor device 10. The electronic device 50 is accommodated in the immersion tank 40 in a state where the board 1 is set upright, as an example. An arrow A in FIG. 1 indicates an upper side of the immersion tank 40. This upper side of the immersion tank 40 corresponds to an upper side in a vertical direction.

Next, a configuration of the semiconductor device 10 will be specifically described.

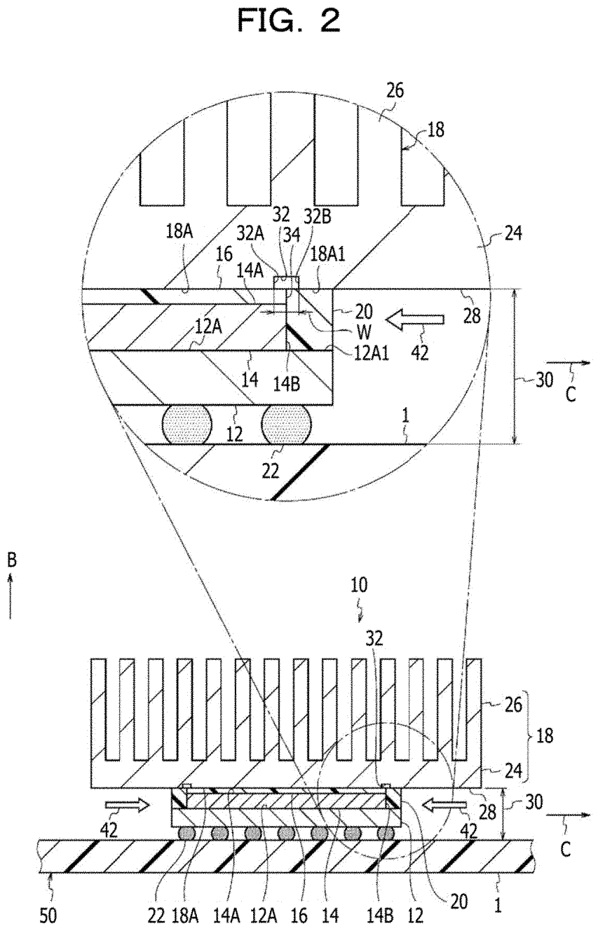

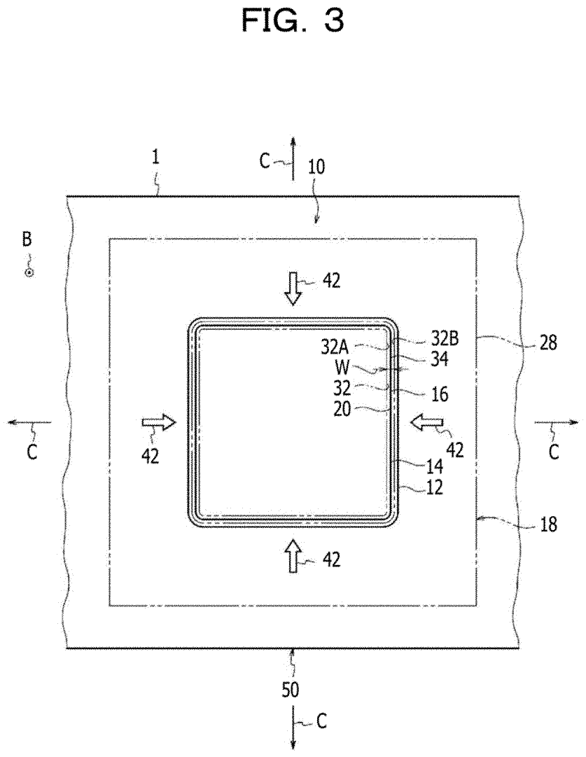

FIGS. 2 and 3 illustrate the semiconductor device 10 of FIG. 1 and a peripheral portion thereof. An arrow B in FIGS. 2 and 3 indicates an upper side of the board 1. In the following description, plan view corresponds to viewing from the arrow B side. As illustrated in FIGS. 2 and 3, the semiconductor device 10 includes a semiconductor chip 12, a heat transfer plate 14, a first adhesive material 16, a radiator 18, and a second adhesive material 20. In FIG. 3, the radiator 18 is indicated by an imaginary line (two-dot chain line) to facilitate understanding of a configuration of the semiconductor device 10.

The semiconductor chip 12 has, for example, a large-scale integration (LSI) circuit. This semiconductor chip 12 is formed in a rectangular flat plate shape in plan view, and is mounted to the board 1. This semiconductor chip 12 is connected to the board 1 via a plurality of solder balls 22.

The heat transfer plate 14 (heat spreader) is formed in a rectangular flat plate shape in plan view. The heat transfer plate 14 is joined to an upper surface 12A of the semiconductor chip 12 via a thermally conductive adhesive material (not illustrated). The heat transfer plate 14 has a smaller plane area than that of the semiconductor chip 12, and the semiconductor chip 12 has a first joint surface 12A1 located at a periphery of the heat transfer plate 14. This first joint surface 12A1 is formed in a loop shape along the periphery of the heat transfer plate 14.

The radiator 18 has a main body 24 having a flat plate shape and a plurality of fins 26 formed on an upper surface of the main body 24. The main body 24 is formed in a flat plate shape having a rectangular shape in plan view. A lower surface of the main body 24 forms a lower surface 18A of the radiator 18. This lower surface 18A of the radiator 18 is joined to an upper surface 14A of the heat transfer plate 14 via the first adhesive material 16 described later.

The radiator 18 has a larger plane area than that of the heat transfer plate 14 described above, and the lower surface 18A of the radiator 18 has a second joint surface 18A1 located at a periphery of the heat transfer plate 14. This second joint surface 18A1 is formed in a loop shape along the periphery of the heat transfer plate 14. The second joint surface 18A1 faces the first joint surface 12A1.

Furthermore, the radiator 18 has a larger plane area than that of the semiconductor chip 12 described above. Therefore, the radiator 18 has an extending portion 28 (eave portion) extending toward an outer peripheral side (an arrow C side) of the board 1 with respect to the semiconductor chip 12. This extending portion 28 is formed in a loop shape along the periphery of the semiconductor chip 12. This extending portion 28 faces the board 1. The extending portion 28 is not provided with a frame part surrounding the semiconductor chip 12, and a gap 30 between the extending portion 28 and the board 1 is open toward the outer peripheral side of the board 1 (the arrow C side). This gap 30 is formed in a loop shape along the periphery of the semiconductor chip 12.

The first adhesive material 16 has substantially the same size and shape as the upper surface 14A of the heat transfer plate 14, and is provided on the entire upper surface 14A of the heat transfer plate 14. The second adhesive material 20 is provided in a loop shape along the periphery of the heat transfer plate 14, and is bonded to an outer peripheral surface 14B of the heat transfer plate 14. Furthermore, this second adhesive material 20 is bonded to the first joint surface 12A1 of the upper surface 12A of the semiconductor chip 12, and to the second joint surface 18A1 of the lower surface 18A of the radiator 18, and joins the first joint surface 12A1 with the second joint surface 18A1.

The first adhesive material 16 is a thermally conductive adhesive material having higher thermal conductivity than that of the second adhesive material 20. Whereas, the second adhesive material 20 is a structural adhesive material (sealing adhesive material) having higher resistance to the refrigerant liquid 42 than that of the first adhesive material 16. The second adhesive material 20 has a higher adhesive strength than that of the first adhesive material 16. As each of the first adhesive material 16 and the second adhesive material 20, as an example, a paste-form thermosetting adhesive material is used.

On the lower surface 18A of the radiator 18, a groove 32 that opens on the semiconductor chip 12 side (lower side) is formed. A cross-sectional shape of the groove 32 cut along a plane orthogonal to a longitudinal direction of the groove 32 is, as an example, a rectangular shape. This groove 32 extends in a loop shape along the outer peripheral surface 148 of the heat transfer plate 14.

More specifically, for example, the groove 32 has an inner peripheral side surface 32A located on an inner peripheral side of the groove 32, and an outer peripheral side surface 32B located on an outer peripheral side of the groove 32. The inner peripheral side surface 32A is formed smaller than the outer peripheral surface 14B (outer shape) of the heat transfer plate 14, and the outer peripheral side surface 32B is formed larger than the outer peripheral surface 14B (outer shape) of the heat transfer plate 14. The radiator 18 is positioned with respect to the heat transfer plate 14 so that the outer peripheral surface 14B of the heat transfer plate 14 is located inside a width W between the inner peripheral side surface 32A and the outer peripheral side surface 328, and is fixed to the heat transfer plate 14.

As will be described later, this groove 32 functions as an escape groove into which an extra portion of the first adhesive material 16 and an extra portion of the second adhesive material 20 enter individually. This groove 32 has a sufficient capacity to accommodate the extra portion of the first adhesive material 16 and the extra portion of the second adhesive material 20.

In the present embodiment, there is used a sufficient amount of the first adhesive material 16 to spread over the entire upper surface 14A of the heat transfer plate 14. Furthermore, there is used a sufficient amount of the second adhesive material 20 to adhere to the first joint surface 12A1 of the semiconductor chip 12 and the second joint surface 18A1 of the radiator 18. The first adhesive material 16 and the second adhesive material 20 individually flow toward the groove 32, and an extra portion of the first adhesive material 16 and an extra portion of the second adhesive material 20 individually enter the groove 32. The first adhesive material 16 and the second adhesive material 20 are adjacent to each other in the vicinity of the groove 32 by individually flowing toward the groove 32.

Between these first adhesive material 16 and second adhesive material 20, a boundary 34 extending in a loop shape along the outer peripheral surface 14B of the heat transfer plate 14 is formed. Note that the second adhesive material 20 may be in contact with the first adhesive material 16 over the entire periphery of the boundary 34, or may be separated from the first adhesive material 16 over the entire periphery of the boundary 34. Furthermore, a part of the second adhesive material 20 in a peripheral direction may be in contact with the first adhesive material 16, and the remaining part of the second adhesive material 20 in the peripheral direction may be separated from the first adhesive material 16. The groove 32 is located at the boundary 34 between the first adhesive material 16 and the second adhesive material 20. That is, for example, in plain view of the groove 32 and the boundary 34, the groove 32 overlaps with the boundary 34.

Next, a method for manufacturing a semiconductor device according to the present embodiment will be described.

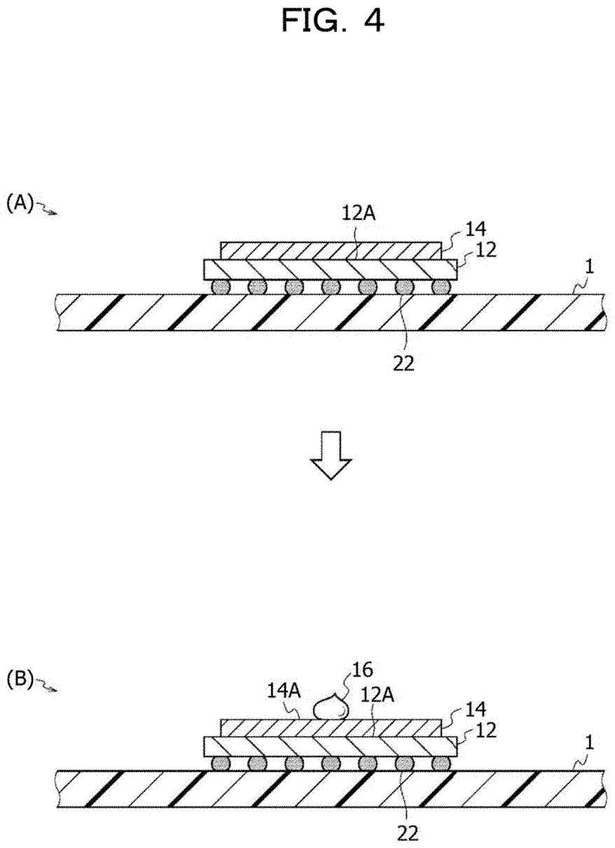

FIG. 4 illustrates a first process of the method for manufacturing the semiconductor device according to the present embodiment. First, as illustrated in step (A) of FIG. 4, the semiconductor chip 12 is mounted to the board 1. At this time, the semiconductor chip 12 is connected to the board 1 via a plurality of solder balls 22. Furthermore, the heat transfer plate 14 is joined to the upper surface 12A of the semiconductor chip 12 via a thermally conductive adhesive material (not illustrated).

Subsequently, as illustrated in step (B) of FIG. 4, an uncured first adhesive material 16 is applied to a center of the upper surface 14A of the heat transfer plate 14. At this time, an amount of the first adhesive material 16 is sufficient to spread over the entire upper surface 14A of the heat transfer plate 14.

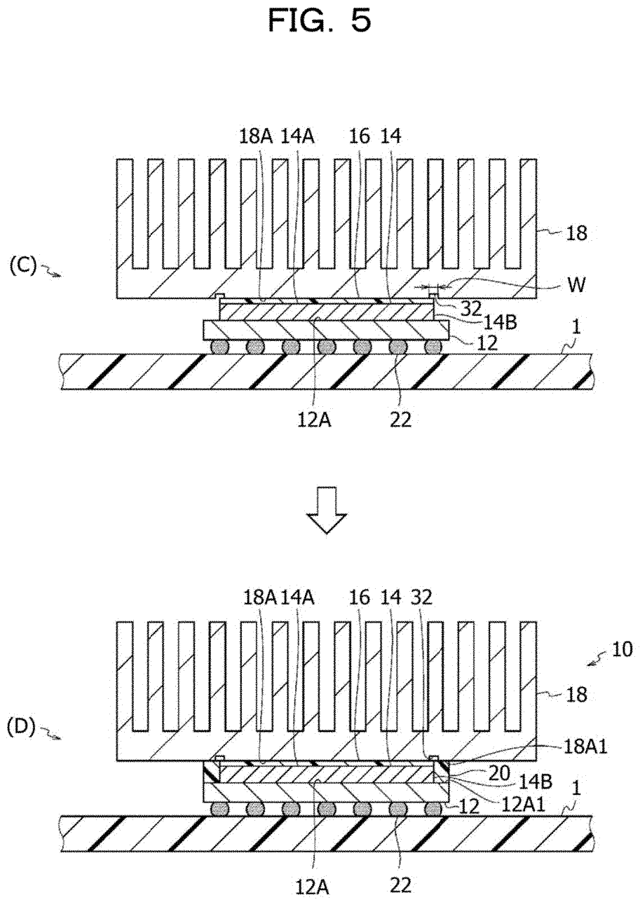

FIG. 5 illustrates a second process of the method for manufacturing the semiconductor device according to the present embodiment. As illustrated in step (C) of FIG. 5, the radiator 18 is placed on the upper surface 14A of the heat transfer plate 14 via the first adhesive material 16. At this time, the radiator 18 is positioned with respect to the heat transfer plate 14 so that the outer peripheral surface 14B of the heat transfer plate 14 is located inside the width W of the groove 32. Then, the first adhesive material 16 is crushed by the lower surface 18A of the radiator 18.

Here, an amount of the first adhesive material 16 is made sufficient to spread over the entire upper surface 14A of the heat transfer plate 14. Therefore, by the first adhesive material 16 being crushed by the lower surface 18A of the radiator 18, the first adhesive material 16 is spread over the entire upper surface 14A of the heat transfer plate 14. Then, an extra portion of the first adhesive material 16 flows toward the groove 32 and enters the groove 32. This suppresses protrusion of the first adhesive material 16 toward the outer peripheral side of the groove 32 while the first adhesive material 16 spreads toward the groove 32 side. Then, the first adhesive material 16 is cured, and the lower surface 18A of the radiator 18 is joined to the upper surface 14A of the heat transfer plate 14 via the first adhesive material 16.

Subsequently, as illustrated in step (D) of FIG. 5, an uncured second adhesive material 20 is applied to the outer peripheral surface 14B of the heat transfer plate 14. At this time, an amount of the second adhesive material 20 is made sufficient to adhere to the first joint surface 12A1 of the semiconductor chip 12 and the second joint surface 18A1 of the radiator 18. This second adhesive material 20 is located on the opposite side of the groove 32 from the first adhesive material 16.

Then, an extra portion of the second adhesive material 20 flows toward the groove 32 and enters the groove 32. This suppresses protrusion of the second adhesive material 20 toward the inner peripheral side of the groove 32 while the second adhesive material 20 spreads toward the groove 32 side. Furthermore, the first adhesive material 16 and the second adhesive material 20 are adjacent to each other in the vicinity of the groove 32 by individually flowing toward the groove 32. Then, the second adhesive material 20 is cured, and the lower surface 18A of the radiator 18 is joined to the upper surface 12A of the semiconductor chip 12 via the second adhesive material 20. The semiconductor device 10 is manufactured in the manner described above.

Next, operations and effects of the present embodiment will be described.

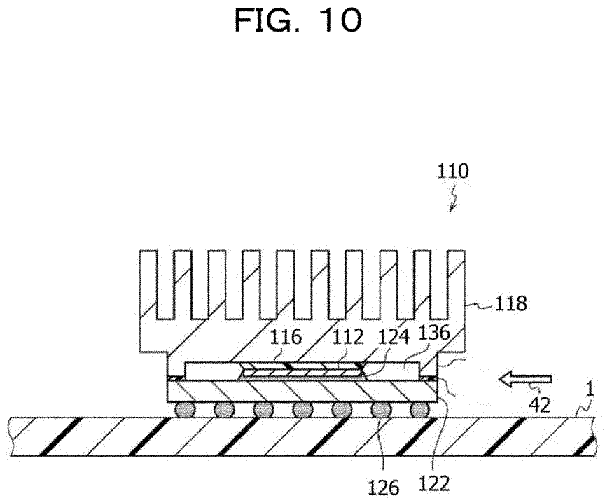

First, a comparative example will be described in order to clarify operations and effects according to the present embodiment. FIG. 10 illustrates a semiconductor device 110 according to the comparative example in a state of being mounted to a board 1. The semiconductor device 110 according to the comparative example includes a semiconductor chip 112, a first adhesive material 116, a radiator 118, a second adhesive material 120, a package board 122, and an underfill material 124.

The package board 122 is connected to the board 1 via a plurality of solder balls 126, and the semiconductor chip 112 is connected to an upper surface of the package board 122 via a plurality of solder balls (not illustrated). The underfill material 124 is provided between the semiconductor chip 112 and the package board 122.

A lower surface of the radiator 118 is joined to an upper surface of the semiconductor chip 112 via the first adhesive material 116. The lower surface of the radiator 118 is formed with a frame part 132 surrounding the semiconductor chip 112, and the frame part 132 is joined to the package board 122 via the second adhesive material 120. Between the second adhesive material 120 joining the frame part 132 to the package board 122 and the first adhesive material 116 joining the radiator 118 to the semiconductor chip 112, a space 136 is provided.

However, in the semiconductor device 110 according to the comparative example described above, pressure in the space 136 between the first adhesive material 116 and the second adhesive material 120 may increase accompanying heat generation of the semiconductor chip 112. In this case, pressure may be applied to the second adhesive material 120, and a sealing property of the second adhesive material 120 may be impaired. Therefore, when the semiconductor device 110 according to the comparative example described above is used for an electronic device 50 (see FIG. 1) to be immersed in a refrigerant liquid 42, it is assumed that the refrigerant liquid 42 passes through the second adhesive material 120 to reach the first adhesive material 116, and the first adhesive material 116 is exposed to the refrigerant liquid 42. When the first adhesive material 116 is exposed to the refrigerant liquid 42 in this way, the first adhesive material 116 may be deteriorated, and thermal conductivity of the first adhesive material 116 may be impaired.

In contrast, as illustrated in FIG. 2, according to the semiconductor device 10 of the present embodiment, a heat transfer plate 14 having a smaller plane area than that of the semiconductor chip 12 is joined to an upper surface 12A of the semiconductor chip 12. Then, the lower surface 18A of the radiator 18 is joined to the upper surface 14A of the heat transfer plate 14 via the first adhesive material 16. Furthermore, the radiator 18 has a plane area larger than that of the heat transfer plate 14, and the upper surface 12A of the semiconductor chip 12 is joined to the lower surface 18A of the radiator 18 via the second adhesive material 20 provided on the outer peripheral surface 14B of the heat transfer plate 14.

Here, the lower surface 18A of the radiator 18 is formed with the groove 32 extending along the outer peripheral surface 148 of the heat transfer plate 14. This groove 32 functions as an escape groove into which an extra portion of the first adhesive material 16 and an extra portion of the second adhesive material 20 enter individually. Therefore, it is possible to use a sufficient amount of the first adhesive material 16 to spread over the entire upper surface 14A of the heat transfer plate 14. Similarly, there may be used a sufficient amount of the second adhesive material 20 to adhere to the first joint surface 12A1 of the semiconductor chip 12 and the second joint surface 18A1 of the radiator 18.

Then, as described above, by using a sufficient amount of the first adhesive material 16 and the second adhesive material 20, the first adhesive material 16 and the second adhesive material 20 individually flow toward the groove 32, and are adjacent to each other in the vicinity of the groove 32. This can remove or reduce the space between the first adhesive material 16 and the second adhesive material 20. Therefore, pressure applied to the second adhesive material 20 is suppressed and the sealing property of the second adhesive material 20 is maintained, even when the semiconductor chip 12 generates heat. Therefore, it is possible to inhibit the refrigerant liquid 42 from passing through the second adhesive material 20 to reach the first adhesive material 16. As a result, it is possible to suppress exposure of the first adhesive material 16 to the refrigerant liquid 42, and therefore to suppress impairment of thermal conductivity of the first adhesive material 16.

In addition, according to the semiconductor device 10 of the present embodiment, even when the first adhesive material 16 is applied in a larger amount than that to spread over the entire surface of the upper surface 14A of the heat transfer plate 14, an extra portion of the first adhesive material 16 enters the groove 32. This can suppress protrusion of the first adhesive material 16 toward the outer peripheral side of the groove 32. Similarly, even when the second adhesive material 20 is applied in a larger amount than an amount to adhere to the first joint surface 12A1 of the semiconductor chip 12 and the second joint surface 18A1 of the radiator 18, an extra portion of the second adhesive material 20 enters the groove 32. This can suppress protrusion of the second adhesive material 20 toward the inner peripheral side of the groove 32.

As a result, it is possible to suppress excessive mutual interference of portions of the first adhesive material 16 and the second adhesive material 20 other than the portion that has entered the groove 32 (that is, for example, portions that contribute to joining). This can suppress reaction of the first adhesive material 16 and the second adhesive material 20 and deterioration of individual properties, and an adhesive thickness and an adhesive area can be secured for each of the first adhesive material 16 and the second adhesive material 20.

Furthermore, according to the semiconductor device 10 of the present embodiment, it is possible to use a sufficient amount of the first adhesive material 16 to spread over the entire upper surface 14A of the heat transfer plate 14. This allows the first adhesive material 16 to be spread over the entire upper surface 14A of the heat transfer plate 14, and therefore can improve the heat transfer between the heat transfer plate 14 and the radiator 18 joined via the first adhesive material 16.

Similarly, there may be used a sufficient amount of the second adhesive material 20 to adhere to the first joint surface 12A1 of the semiconductor chip 12 and the second joint surface 18A1 of the radiator 18. This allows the second adhesive material 20 to be spread over the entire surface of each of the first joint surface 12A1 and the second joint surface 18A1, and therefore can improve each of an adhesive strength between the second adhesive material 20 and the semiconductor chip 12 and an adhesive strength between the second adhesive material 20 and the radiator 18.

Furthermore, the radiator 18 is positioned with respect to the heat transfer plate 14 so that the outer peripheral surface 148 of the heat transfer plate 14 is located inside the width W between the inner peripheral side surface 32A and the outer peripheral side surface 32B. Therefore, since the groove 32 is located at the boundary 34 between the first adhesive material 16 and the second adhesive material 20, it is possible to suppress protrusion of the first adhesive material 16 toward the outer peripheral side of the groove 32 and protrusion of the second adhesive material 20 toward the inner peripheral side of the groove 32 in a well-balanced manner. This can more effectively suppress excessive mutual interference of the first adhesive material 16 and the second adhesive material 20.

Furthermore, according to the electronic device 50 of the present embodiment, the radiator 18 has the extending portion 28 extending toward the outer peripheral side (the arrow C side) of the board 1 with respect to the semiconductor chip 12, and the gap 30 between the extending portion 28 and the board 1 is open toward the outer peripheral side of the board 1 (the arrow C side). Therefore, the refrigerant liquid 42 flows between the extending portion 28 and the board 1 through this gap 30, and this refrigerant liquid 42 is directly supplied to the semiconductor chip 12. This can improve the cooling efficiency of the semiconductor chip 12.

Furthermore, according to the method for manufacturing a semiconductor device of the present embodiment illustrated in FIGS. 4 and 5, after the first adhesive material 16 is cured, the second adhesive material 20 is applied to the outer peripheral surface 14B of the heat transfer plate 14. Therefore, it is possible to suppress an uncured first adhesive material 16 from being pushed by the second adhesive material 20. This can secure an adhesive thickness and an adhesive area of the first adhesive material 16.

Next, modified examples of the present embodiment will be described.

### First Modified Example

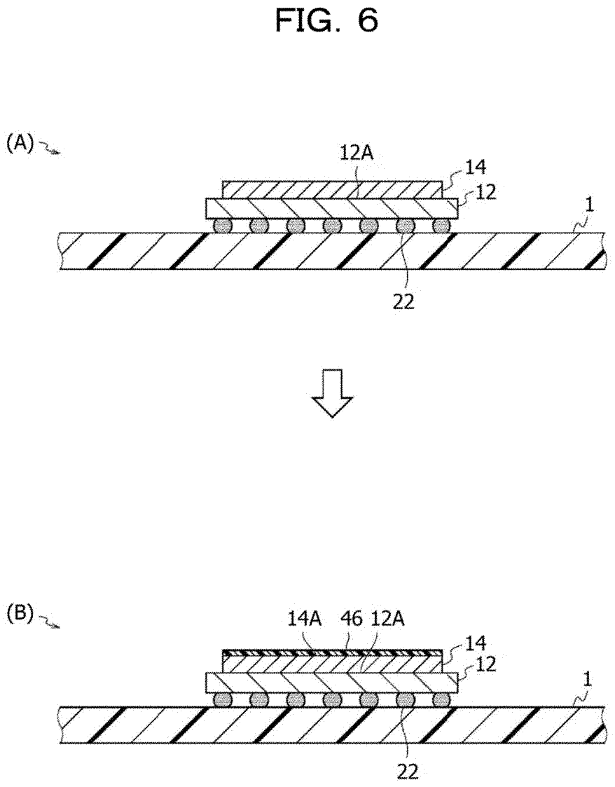

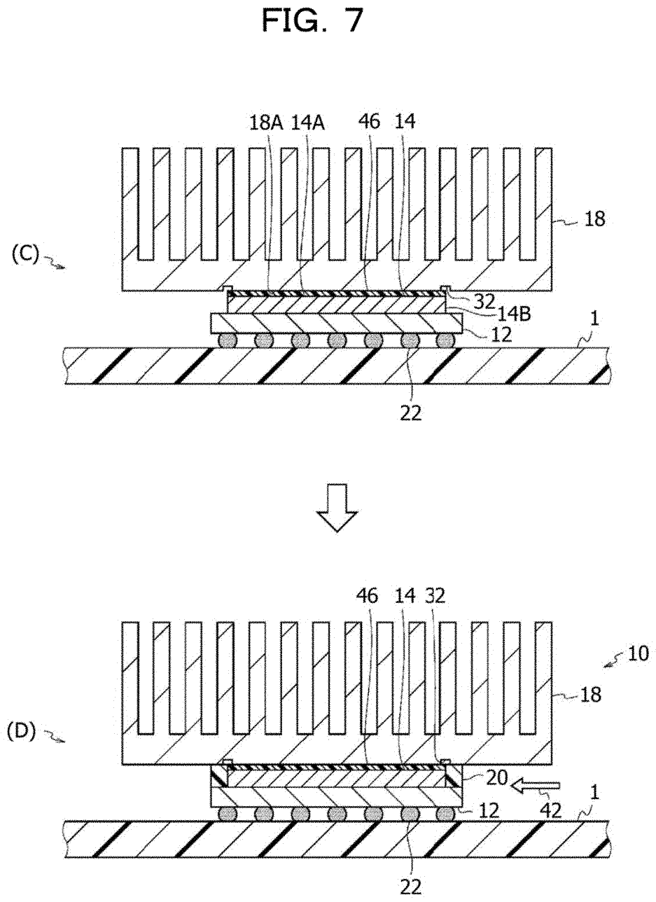

FIGS. 6 and 7 illustrate a first modified example of the method for manufacturing the semiconductor device according to the present embodiment. In this first modified example, a tape-shaped first adhesive material 46 is used instead of the paste-form first adhesive material 16 (see FIGS. 2 to 5), with respect to the embodiment described above. This first adhesive material 46 is, for example, a thermal interface material (TIM), and is a thermally conductive adhesive material having higher thermal conductivity than that of a second adhesive material 20.

In this first modified example, step (A) is the same as that in the embodiment described above. In this first modified example, step (B) and step (C) are changed as follows from the embodiment described above. In other words, for example, in step (B), an uncured first adhesive material 46 is attached to an upper surface 14A of a heat transfer plate 14. At this time, a size of the first adhesive material 46 is sufficient to spread over the entire upper surface 14A of the heat transfer plate 14. Subsequently, in step (C), a radiator 18 is placed on the upper surface 14A of the heat transfer plate 14 via the first adhesive material 46, and the first adhesive material 46 is crushed by a lower surface 18A of the radiator 18.

Here, the first adhesive material 46 has a size sufficient to spread over the entire upper surface 14A of the heat transfer plate 14. Therefore, by the first adhesive material 46 being crushed by the lower surface 18A of the radiator 18, the first adhesive material 46 is spread over the entire upper surface 14A of the heat transfer plate 14. Then, an extra portion of the first adhesive material 46 flows toward a groove 32 and enters the groove 32. This suppresses protrusion of the first adhesive material 46 toward an outer peripheral side of the groove 32 while the first adhesive material 46 spreads toward the groove 32 side. Then, the first adhesive material 46 is cured, and the lower surface 18A of the radiator 18 is joined to the upper surface 14A of the heat transfer plate 14 via the first adhesive material 46. Step (D) is the same as that in the embodiment described above.

Also in the first modified example, similarly to the embodiment described above, the first adhesive material 46 and the second adhesive material 20 individually flow toward the groove 32, and are adjacent to each other in the vicinity of the groove 32. This can remove or reduce the space between the first adhesive material 46 and the second adhesive material 20. Therefore, pressure applied to the second adhesive material 20 is suppressed and the sealing property of the second adhesive material 20 is maintained, even when the semiconductor chip 12 generates heat. Therefore, it is possible to inhibit a refrigerant liquid 42 from passing through the second adhesive material 20 to reach the first adhesive material 46. As a result, it is possible to suppress exposure of the first adhesive material 46 to the refrigerant liquid 42, and therefore to suppress impairment of thermal conductivity of the first adhesive material 46.

### Second Modified Example

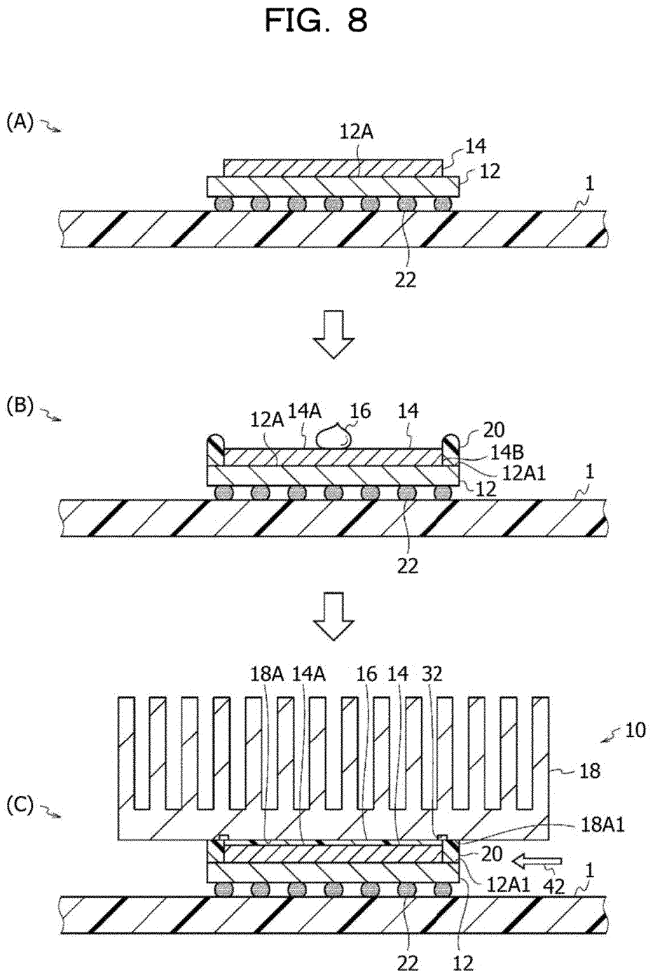

FIG. 8 illustrates a second modified example of the method for manufacturing the semiconductor device according to the present embodiment. In this second modified example, step (A) is the same as that in the embodiment described above. In this second modified example, step (B) and step (C) are changed as follows from the embodiment described above.

In other words, for example, in step (B), an uncured first adhesive material 16 is applied to an upper surface 14A of a heat transfer plate 14, and an uncured second adhesive material 20 is applied to an outer peripheral surface 14B of the heat transfer plate 14. At this time, an amount of the first adhesive material 16 is sufficient to spread over the entire upper surface 14A of the heat transfer plate 14. Similarly, an amount of the second adhesive material 20 is made sufficient to adhere to a first joint surface 12A1 of a semiconductor chip 12 and a second joint surface 18A1 of a radiator 18. Subsequently, in step (C), the radiator 18 is placed on the upper surface 14A of the heat transfer plate 14 via the first adhesive material 16, and the first adhesive material 16 and the second adhesive material 20 are crushed by the lower surface 18A of the radiator 18.

Here, an amount of the first adhesive material 16 is made sufficient to spread over the entire upper surface 14A of the heat transfer plate 14. Therefore, by the first adhesive material 16 being crushed by the lower surface 18A of the radiator 18, the first adhesive material 16 is spread over the entire upper surface 14A of the heat transfer plate 14. Then, an extra portion of the first adhesive material 16 flows toward the groove 32 and enters the groove 32. This suppresses protrusion of the first adhesive material 16 toward the outer peripheral side of the groove 32 while the first adhesive material 16 spreads toward the groove 32 side.

Similarly, an amount of the second adhesive material 20 is made sufficient to adhere to the first joint surface 12A1 of the semiconductor chip 12 and the second joint surface 18A1 of the radiator 18. Therefore, by the second adhesive material 20 being crushed by the lower surface 18A of the radiator 18, the second adhesive material 20 is spread over the entire second joint surface 18A1 of the radiator 18. Then, an extra portion of the second adhesive material 20 flows toward the groove 32 and enters the groove 32. This suppresses protrusion of the second adhesive material 20 toward the inner peripheral side of the groove 32 while the second adhesive material 20 spreads toward the groove 32 side.

Also in the second modified example, similarly to the embodiment described above, the first adhesive material 16 and the second adhesive material 20 individually flow toward the groove 32, and are adjacent to each other in the vicinity of the groove 32. This can remove or reduce the space between the first adhesive material 16 and the second adhesive material 20. Therefore, pressure applied to the second adhesive material 20 is suppressed and the sealing property of the second adhesive material 20 is maintained, even when the semiconductor chip 12 generates heat. Therefore, it is possible to inhibit the refrigerant liquid 42 from passing through the second adhesive material 20 to reach the first adhesive material 16. As a result, it is possible to suppress exposure of the first adhesive material 16 to the refrigerant liquid 42, and therefore to suppress impairment of thermal conductivity of the first adhesive material 16.

### Third Modified Example

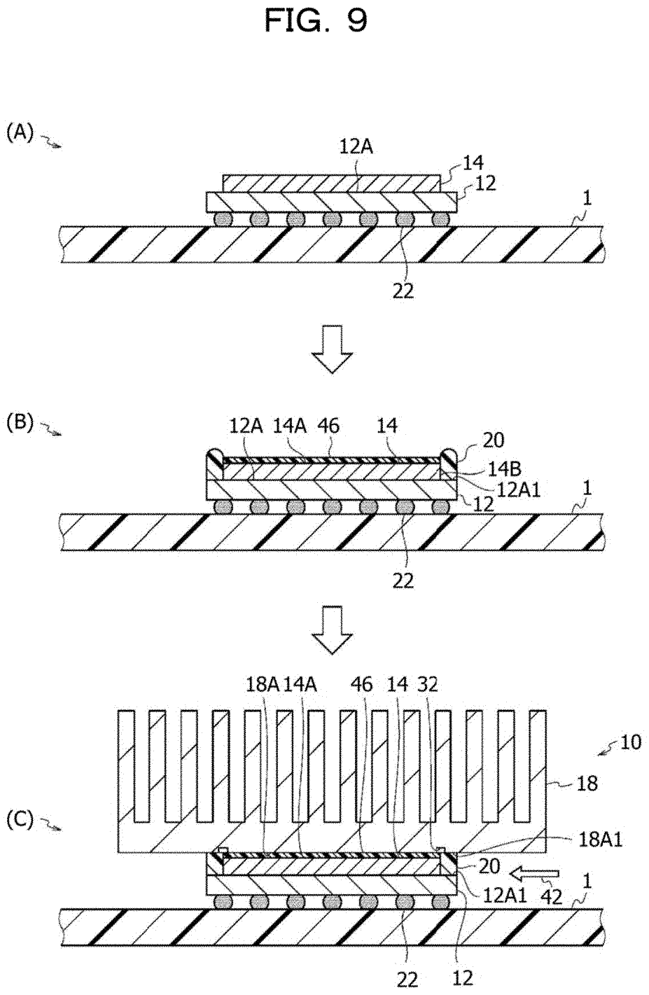

FIG. 9 illustrates a third modified example of the method for manufacturing the semiconductor device according to the present embodiment. In this third modified example, a tape-shaped first adhesive material 46 is used instead of the paste-form first adhesive material 16 (see FIGS. 2 to 5), with respect to the embodiment described above.

In this third modified example, step (A) is the same as that in the embodiment described above. In this third modified example, step (B) and step (C) are changed as follows from the embodiment described above.

In other words, for example, in step (B), an uncured first adhesive material 46 is attached to an upper surface 14A of a heat transfer plate 14, and an uncured second adhesive material 20 is applied to an outer peripheral surface 14B of the heat transfer plate 14. At this time, a size of the first adhesive material 46 is sufficient to spread over the entire upper surface 14A of the heat transfer plate 14. Similarly, an amount of the second adhesive material 20 is made sufficient to adhere to a first joint surface 12A1 of a semiconductor chip 12 and a second joint surface 18A1 of a radiator 18. Subsequently, in step (C), the radiator 18 is placed on the upper surface 14A of the heat transfer plate 14 via the first adhesive material 46, and the first adhesive material 46 and the second adhesive material 20 are crushed by the lower surface 18A of the radiator 18.

Here, the first adhesive material 46 has a size sufficient to spread over the entire upper surface 14A of the heat transfer plate 14. Therefore, by the first adhesive material 46 being crushed by the lower surface 18A of the radiator 18, the first adhesive material 46 is spread over the entire upper surface 14A of the heat transfer plate 14. Then, an extra portion of the first adhesive material 46 flows toward a groove 32 and enters the groove 32. This suppresses protrusion of the first adhesive material 46 toward an outer peripheral side of the groove 32 while the first adhesive material 46 spreads toward the groove 32 side.

Similarly, an amount of the second adhesive material 20 is made sufficient to adhere to the first joint surface 12A1 of the semiconductor chip 12 and the second joint surface 18A1 of the radiator 18. Therefore, by the second adhesive material 20 being crushed by the lower surface 18A of the radiator 18, the second adhesive material 20 is spread over the entire second joint surface 18A1 of the radiator 18. Then, an extra portion of the second adhesive material 20 flows toward the groove 32 and enters the groove 32. This suppresses protrusion of the second adhesive material 20 toward the inner peripheral side of the groove 32 while the second adhesive material 20 spreads toward the groove 32 side.

Also in the third modified example, similarly to the embodiment described above, the first adhesive material 46 and the second adhesive material 20 individually flow toward the groove 32, and are adjacent to each other in the vicinity of the groove 32. This can remove or reduce the space between the first adhesive material 46 and the second adhesive material 20. Therefore, pressure applied to the second adhesive material 20 is suppressed and the sealing property of the second adhesive material 20 is maintained, even when the semiconductor chip 12 generates heat. Therefore, it is possible to inhibit a refrigerant liquid 42 from passing through the second adhesive material 20 to reach the first adhesive material 46. As a result, it is possible to suppress exposure of the first adhesive material 46 to the refrigerant liquid 42, and therefore to suppress impairment of thermal conductivity of the first adhesive material 46.

Note that, in the second and third modified examples described above, the paste-form second adhesive material 20 is used, but a second adhesive material 20 preformed in a loop shape may be used.

### Other Modified Examples

In the embodiment described above, the semiconductor device 10 is applied to the electronic device 50 to be immersed in the refrigerant liquid 42 as a more preferable example, but may be applied to an electronic device not to be immersed in the refrigerant liquid 42. Furthermore, when the semiconductor device 10 is applied to an electronic device not to be immersed in the refrigerant liquid 42, a material that does not have resistance to the refrigerant liquid 42 may be used as the second adhesive material 20.

Furthermore, in the embodiment described above, the outer peripheral surface 14B of the heat transfer plate 14 is located inside the width W between the inner peripheral side surface 32A and the outer peripheral side surface 32B as a more preferable example, but may be located outside the width W.

Next, examples of the present embodiment will be described.

### First Example

A first example corresponds to an example of FIG. 8 described above. In this first example, for example, TC-4525 manufactured by Dow Corning Toray Co., Ltd. was used as the paste-form first adhesive material 16. This first adhesive material 16 has a property that a thermal conductivity exceeds 1 W/m·k. As the second adhesive material 20 disposed at the periphery of the first adhesive material 16, there was used DP-460EG manufactured by 3M and having excellent resistance to the assumed refrigerant liquid 42, Fluorinert (trademark) manufactured by 3M.

In a joining step of the radiator 18, first, the paste-form first adhesive material 16 was applied to the upper surface 14A of the heat transfer plate 14, and then the paste-form second adhesive material 20 was applied to the outer peripheral surface 14 of the heat transfer plate 14. Then, the radiator 18 was placed on the heat transfer plate 14 and pressed, the radiator 18 was joined to the heat transfer plate 14 with the first adhesive material 16, and the radiator 18 was joined to the semiconductor chip 12 with the second adhesive material 20.

Since both the first adhesive material 16 and the second adhesive material 20 are of a type of being cured at room temperature, the curing is completed by allowing the radiator 18 to stand still for a certain period of time under its own weight. Due to the material properties, the first adhesive material 16 completes the adhesion and curing in a shorter time than that of the second adhesive material 20. Then, a sample of the semiconductor device 10 was completed in the manner described above.

According to this sample of the semiconductor device 10, pressure applied to the second adhesive material 20 is suppressed even when the semiconductor chip 12 generates heat. Therefore, since the sealing property of the second adhesive material 20 is maintained, it is possible to inhibit the refrigerant liquid 42 from passing through the second adhesive material 20 to reach the first adhesive material 16. This suppresses exposure of the first adhesive material 16 to the refrigerant liquid 42, and therefore can suppress impairment of thermal conductivity of the first adhesive material 16.

### Second Example

A second example corresponds to an example of FIG. 9 described above. In this second example, for example, 8926-025 manufactured by 3M was used as the tape-shaped first adhesive material 46. This first adhesive material 46 also has a property that a thermal conductivity exceeds 1 W/m-k.

In a joining step of the radiator 18, first, the tape-shaped first adhesive material 46 was attached to the upper surface 14A of the heat transfer plate 14, and then the paste-form second adhesive material 20 was applied to the outer peripheral surface 148 of the heat transfer plate 14. Then, the radiator 18 was placed on the heat transfer plate 14 and pressed, the radiator 18 was joined to the heat transfer plate 14 with the first adhesive material 46, and the radiator 18 was joined to the semiconductor chip 12 with the second adhesive material 20. Then, a sample of the semiconductor device 10 was completed in the manner described above.

According to this sample of the semiconductor device 10, pressure applied to the second adhesive material 20 is suppressed even when the semiconductor chip 12 generates heat. Therefore, since the sealing property of the second adhesive material 20 is maintained, it is possible to inhibit the refrigerant liquid 42 from passing through the second adhesive material 20 to reach the first adhesive material 46. This suppresses exposure of the first adhesive material 46 to the refrigerant liquid 42, and therefore can suppress impairment of thermal conductivity of the first adhesive material 46.

While the embodiments of the technique disclosed in the present application have been described thus far, the technique disclosed in the present application is not limited to the above embodiments and, in addition to the above embodiments, of course may be carried out by making various modifications without departing from the spirit of the invention.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a semiconductor chip;
a heat transfer plate joined to an upper surface of the semiconductor chip;
a first adhesive material provided on an upper surface of the heat transfer plate;
a radiator whose lower surface is joined to the upper surface of the heat transfer plate via the first adhesive material;
a second adhesive material that is provided on an outer peripheral surface of the heat transfer plate, and joins the upper surface of the semiconductor chip and the lower surface of the radiator; and
a groove that is formed on the lower surface of the radiator and extends along the outer peripheral surface of the heat transfer plate.

2. The semiconductor device according to claim 1, wherein
the groove has an inner peripheral side surface located on an inner peripheral side of the groove, and an outer peripheral side surface located on an outer peripheral side of the groove, and
the outer peripheral surface of the heat transfer plate is located inside a width between the inner peripheral side surface and the outer peripheral side surface.

3. An electronic device comprising:
a board;
a semiconductor chip mounted to the board;
a heat transfer plate joined to an upper surface of the semiconductor chip;
a first adhesive material provided on an upper surface of the heat transfer plate;
a radiator whose lower surface is joined to the upper surface of the heat transfer plate via the first adhesive material;
a second adhesive material that is provided on an outer peripheral surface of the heat transfer plate, and joins the upper surface of the semiconductor chip and the lower surface of the radiator; and
a groove that is formed on the lower surface of the radiator and extends along the outer peripheral surface of the heat transfer plate.

4. The electronic device according to claim 3, wherein
the radiator has an extending portion that extends to an outer peripheral side of the board with respect to the semiconductor chip, and
a gap between the extending portion and the board is open toward the outer peripheral side of the board.

5. An Electronic equipment comprising:
an immersion tank that stores a refrigerant liquid; and
an electronic device that is accommodated in the immersion tank and immersed in the refrigerant liquid, wherein
the electronic device includes:
a board;
a semiconductor chip mounted to the board;
a heat transfer plate joined to an upper surface of the semiconductor chip;
a first adhesive material provided on an upper surface of the heat transfer plate;
a radiator whose lower surface is joined to the upper surface of the heat transfer plate via the first adhesive material;
a second adhesive material that is provided on an outer peripheral surface of the heat transfer plate, and joins the upper surface of the semiconductor chip and the lower surface of the radiator; and
a groove that is formed on the lower surface of the radiator and extends along the outer peripheral surface of the heat transfer plate.

6. A method for manufacturing a semiconductor device, the method comprising:
joining a heat transfer plate to an upper surface of a semiconductor chip;
providing a first adhesive material on an upper surface of the heat transfer plate;
joining a lower surface of a radiator in which a groove extending along an outer peripheral surface of the heat transfer plate is formed on the lower surface, to the upper surface of the heat transfer plate via the first adhesive material; and
joining the upper surface of the semiconductor chip and the lower surface of the radiator via a second adhesive material provided on the outer peripheral surface of the heat transfer plate.
